(19) United States
(12) Patent Application Publication
(10) Pub. No.: US 2008/0123335 A1
(43) Pub. Date: May 29, 2008

(54) PRINTED CIRCUIT BOARD ASSEMBLY AND DISPLAY HAVING THE SAME

(76) Inventors: Jong Kun Yoo, Seoul (KR); Soong Yong Joo, Seongnam-Si (KR); Jung Sun Lee, Gwangju-Si (KR); Suk Ki Jung, Suwon-Si (KR); Dong Yub Lee, Siheung-Si (KR)

Correspondence Address: F. CHAU & ASSOCIATES, LLC, 130 WOODBURY ROAD, WOODBURY, NY, 11797, US

(21) Appl. No.: 11/936,944

(22) Filed: Nov. 8, 2007

(30) Foreign Application Priority Data
Nov. 8, 2006 (KR) 10-2006-0110109
Oct. 30, 2007 (KR) 10-2007-0109523

(51) Int. Cl. F21V 23/00; H05K 7/02

(52) U.S. Cl. 362/257; 361/767; 361/749

(57) ABSTRACT

A PCB assembly includes a base, a conductive pattern disposed on the base, a pad provided on a portion of the conductive pattern, a mounting unit disposed on the pad for electrically connecting the conductive pattern and a coverlay having an opening that exposes the mounting unit

### CROSS-REFERENCE TO RELATED PATENT APPLICATIONS

This application claims priority to Korean Patent Application Nos. 10-2006-110109, filed on Nov. 8, 2006, and 10-2007-109523 filed on Oct. 30, 2007, and all the benefits accruing therefrom under 35 U.S.C. §119, the contents of which are herein incorporated by reference in their entireties.

### BACKGROUND OF THE INVENTION

1. Technical Field

The present disclosure relates to electronic devices and, more particularly, to a printed circuit board (“PCB”) assembly and a display having the same.

2. Discussion of Related Art

A flat panel display is a type of display device that can be used to realize small-size, light-weight electronic devices such as a portable computer (e.g., a notebook computer), a personal digital assistant (PDA), and a mobile phone, as well as a monitor of a desktop computer. Examples of a flat panel display include a liquid crystal display (“LCD”), a plasma display panel (“PDP”) and a field emission display (“FED”).

LCDs by virtue of their thin profile, light weight and low power consumption have largely replaced the conventional cathode ray tube (CRT). Currently, LCDs are being applied to small- or pocket-sized devices, such as a cellular phone, a PDA and a portable multimedia player (PMP), and medium- and large-sized devices featuring a flat panel display, such as large-sized monitors and TV panels.

Flexible printed circuit boards are used in various displays including LCDs and other electronic devices. The flexible printed circuit board (FPCB) has been used in realizing miniaturization and integration of displays or the electronic devices due to its good flexibility.

An LCD device includes an LCD panel, an FPCB, a backlight assembly, a mold frame and a bottom chassis. The FPCB, which may be disposed at one side of the LCD panel, drives the LCD panel according to an external signal. The backlight assembly provides light to the LCD panel. The mold frame and the bottom chassis receive the backlight assembly.

For instance, one end of the FPCB may be coupled to one side of the LCD panel and the other end may be bent and positioned on a rear side of the bottom chassis. The FPCB may be coupled to the rear side of the bottom chassis through a fixing member such as a double-sided tape. The ends of the FPCB may be bent in directions opposite to each other by almost 180°.

A plurality of electronic components may be mounted on one side of an end of the FPCB. Because the FPCB is shaped such that both ends are bent in directions opposite to each other, a bending force is distributed over the entire surface of the FPCB, which may cause a mounting of an electronic component to be damaged due to the bending force. For example, the application of the bending force can result in cracking (also referred to as flex cracking) of a copper conductive pattern that is generally connected to the electronic component. Once the crack is created, it may not be readily detected. With time, temperature cycles and increased stress levels, the crack can grow. The flex cracking of the copper conductive pattern, causes lower overall product yield and higher cost per good FPCB, since the cracked parts need to be discarded.

### SUMMARY OF THE INVENTION

Exemplary embodiments of the present invention generally provide a printed circuit board (“PCB”) assembly capable of preventing a flex crack of a conductive pattern by increasing the area of the conductive pattern and covering the conductive pattern with a coverlay, and a display having the PCB assembly.

In accordance with an exemplary embodiment of the present invention, a PCB assembly includes a base, a conductive pattern disposed on the base, a pad provided on a portion of the conductive pattern, a mounting unit disposed on the pad for electrically connecting the conductive pattern, and a coverlay having an opening that exposes the mounting unit, the coverlay substantially covering the conductive pattern.

The area of the pad may be larger than the area of the opening. The PCB assembly may include an electronic component or another PCB electrically connected to the conductive pattern over the mounting unit using a bonding member.

A chamfer or a curved surface may be provided in the opening of the coverlay.

The pad may have a greater width than the conductive pattern in a first direction, the first direction crossing a longitudinal axial (e.g., lengthwise) direction of the conductive pattern.

In accordance with an exemplary embodiment of the present invention, the PCB assembly includes a base, a first conductive pattern disposed on the base and having a protruding pad, a mounting unit mounted on the pad by a bonding member, and a coverlay having an opening exposing the mounting unit and covering the conductive pattern except for a region where the bonding member is provided.

The pad may extend beyond at least a predetermined portion in a first direction, the first direction crossing a longitudinal axial direction of the conductive pattern.

The mounting unit may include an electronic component or another PCB.

A chamfer or a curved surface may be provided on the coverlay to prevent the damage of the mounting unit when the cover layer contacts the mounting unit.

In accordance with an exemplary embodiment of the present invention, a PCB assembly includes a PCB including at least one conductive pattern disposed on a base, and a coverlay configured to cover the conductive pattern, and an electronic component mounted on the PCB, wherein the electronic component is mounted to be connected to the conductive pattern of the PCB by a bonding member, and wherein the coverlay has an opening corresponding to a position where the electronic component and the bonding member are provided.

A pad may be provided on the conductive pattern, the pad having a greater enlarged area than other regions at a connection part between the conductive pattern and the electronic component. The pad may have a larger area than that of the opening.

A circumferential surface of the opening of the coverlay may be provided over the pad, sides of the circumferential surface of the opening 275a being formed of lines having at least two directions or more. The circumferential surface of the opening may have a curved shape over the pad.

The pad may have an enlarged area extending in an opposite direction to another conductive pattern disposed adjacent.

In accordance with an exemplary embodiment of the present invention, a PCB assembly includes a PCB. The PCB includes at least one first conductive pattern disposed on a base, and a coverlay which has and covers the first conductive pattern. The first conductive pattern includes a pad on which a bonding member is placed and a conductive pattern extending from the pad, the pad including an exposed region that is exposed by the opening of the coverlay, and a shielded region that is covered by the coverlay.

The area of the shielded region of the pad may be equal to or greater than the area of the exposed region. The pad may extend in a different direction from another pad adjacent thereto.

The PCB assembly may include a second conductive pattern connected to the first conductive pattern on the PCB using the bonding member.

In accordance with an exemplary embodiment of the present invention, a display includes a display panel configured to display an image, and a PCB having a first side connected to the display panel, a plurality of electronic components mounted on the first side of the PCB, the PCB including at least one conductive pattern disposed on a base, and a coverlay configured to cover the conductive pattern, wherein the electronic component is mounted to be connected to the conductive pattern of the PCB using a bonding member, and the coverlay has an opening corresponding to a position where the electronic component and the bonding member are provided.

The PCB may be provided by bending a second side of the PCB toward a rear side of the display panel.

The PCB may comprise a flexible PCB.

In accordance with an exemplary embodiment of the present invention, a display includes a PCB assembly, and a light source configured to receive power from the PCB assembly. The PCB assembly includes at least one first conductive pattern disposed on a base, and a coverlay which has an opening and is configured to cover the first conductive pattern. The first conductive pattern includes a pad on which a bonding member is placed and a conductive pattern extending from the pad, the pad including an exposed region that is exposed by the opening of the coverlay, and a shielded region that is covered by the coverlay.

The light source may include at least one light-emitting diode (“LED”).

### BRIEF DESCRIPTION OF THE DRAWINGS

The present invention will become readily apparent to those of ordinary skill in the art when descriptions of exemplary embodiments thereof are read with reference to the accompanying drawings.

FIG. 1 is an exploded perspective view of a liquid crystal display (“LCD”) in accordance with an exemplary embodiment of the present invention.

FIG. 2 is a cross-sectional view taken along line A-A of FIG. 1.

FIG. 3A is a plan view illustrating an example of a conventional printed circuit board (“PCB”) assembly.

FIG. 3B is a cross-sectional view taken along line C-C of FIG. 3A.

FIG. 4A is a plan view of a PCB assembly in accordance with an exemplary embodiment of the present invention.

FIG. 4B is a cross-sectional view taken along line E-E of FIG. 4A.

FIGS. 5A and 5B are plan views illustrating the PCB assembly of FIG. 4A, according to exemplary embodiments of the present invention.

FIGS. 6A and 6B are plan views illustrating the PCB assembly of FIG. 4A, according to exemplary embodiments of the present invention.

FIG. 7 is an exploded perspective view illustrating a portion of a backlight assembly, according to an exemplary embodiment of the present invention.

FIG. 8A is a plan view illustrating an example of a conventional PCB assembly.

FIG. 8B is a cross-sectional view taken along line B′-B′ of FIG. 8A.

FIG. 9A is a plan view of a PCB assembly in accordance with an exemplary embodiment of the present invention.

FIG. 9B is a cross-sectional view taken along line C′-C′ of FIG. 9A.

FIGS. 10A to 10C are cross-sectional views illustrating the PCB assembly of FIG. 9B, according to exemplary embodiments of the present invention.

### DESCRIPTION OF EXEMPLARY EMBODIMENTS

Hereinafter, exemplary embodiments of the present invention will be will be described in detail with reference to the accompanying drawings. In the drawings, the sizes and thicknesses of layers and regions may be exaggerated for clarity. Like reference numerals may refer to similar or identical elements throughout the description of the figures.

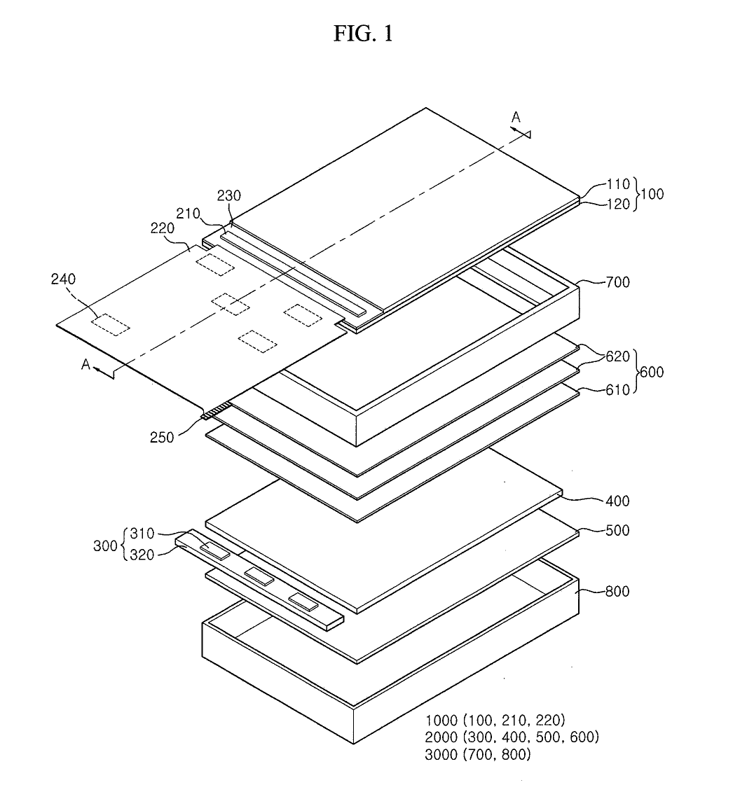

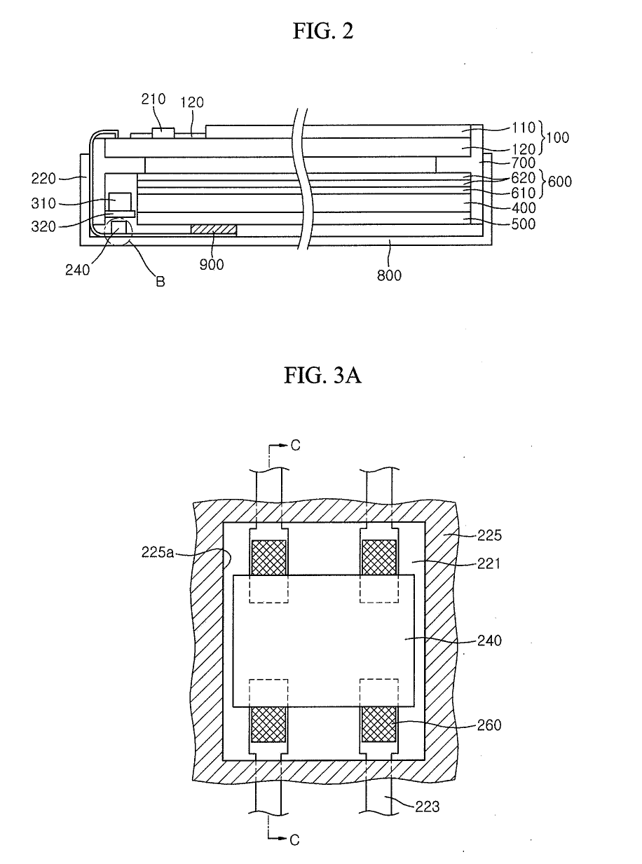

FIG. 1 is an exploded perspective view of an LCD in accordance with an exemplary embodiment of the present invention. FIG. 2 is a cross-sectional view taken along line A-A of FIG. 1.

Referring to FIGS. 1 and 2, the exemplary LCD includes a display assembly 1000 (100, 210, 220), a backlight assembly 2000 (300, 400, 500, 600) configured to provide light to the display assembly 1000, a receiving member configured to receive and fix the display assembly 1000 and the backlight assembly 2000.

The display assembly 1000 includes an LCD panel 100, an integrated circuit (“IC”) chip 210 mounted at one side of the LCD panel 100, and an FPCB 220 having one end connected to the LCD panel 100.

The LCD panel 100 includes a color filter (“CF”) substrate 110 and a thin film transistor (“TFT”) substrate 120 disposed under the CF substrate 110. The CF substrate 110 includes a color filter (not shown) provided thereon and a common electrode (not shown) disposed on the color filter. For example, the common electrode may be formed of a transparent conductive material such as indium tin oxide (ITO) or indium zinc oxide (IZO).

The TFT substrate 120 includes a plurality of TFTs (not shown) arranged in a matrix form. For example, each of the TFTs may be provided with a source terminal connected to a data line, a gate terminal connected to a gate line, and a drain terminal connected to a pixel electrode. The IC chip 210 is mounted at one side of the TFT substrate 120. The IC chip 210 generates signals for driving the LCD panel 100, such as for example, a data signal, a gate driving signal, and a plurality of timing signals for timely applying these signals, and further applies the gate driving signal and a data driving signal to the gate line and the data line of the LCD panel 100, respectively. A portion of the FPCB 220 is connected to one side of the TFT substrate 120. In an exemplary embodiment of the present invention, the FPCB 220 converts an analog type external signal, which is inputted through a pad 250 disposed at an end of the FPCB 220, into a digital signal, and supplies the converted digital signal to the IC chip 210.

A plurality of electronic components 240 is mounted on one surface of the FPCB 220 as illustrated in FIGS. 1 and 2, and is received in a receiving space provided in a mold frame 700. A passivation layer 230 may be coated on a portion of the TFT substrate 120 to protect the IC chip 210 and the FPCB 220 mounted on the TFT substrate 120. For example, the passivation layer 230 is provided to cover a periphery of the IC chip 210 and the FPCB 220.

The backlight assembly 2000 includes a light source 300, a light guide plate 400 coupled with the light source 300, a reflection plate 500 provided under the light guide plate 400, and an optical sheet 600 provided over the light guide plate 400. The light source 300, which is provided at a side of the light guide plate 400, includes LEDs 310 and a substrate 320 with the LEDs 310 mounted thereon. The LED 310 is a side view type LED, and thus emits light toward the side of the light guide plate 400. The substrate 320 is an FPCB with good flexibility in which a circuitry (not shown) is provided and external power is supplied to the LED 310 through the circuitry.

Although FIG. 1 illustrates that the light source 300 is provided at one side of the light guide plate 400 disposed under a driving unit 210 and 220 of the LCD panel 100, it is to be understood that the light guide plate 400 may be disposed in various locations. For example, the light source 300 may be disposed under the driving unit 210 and 220, and may be received in the mold frame 700.

The light guide plate 400, which is coupled to one side of the light source 300 may have the shape of a rectangular plate. Optical distribution of light from the light source 300 is converted from point or line light into surface light. The reflection plate 500 is provided under the light guide plate 400 and reflects the light emitted to the bottom of the light guide plate 400 toward a light-emitting surface of the backlight assembly 2000, thus improving light efficiency. In an exemplary embodiment of the present invention, the reflection plate 500 adjusts the reflection amount of total incident light to thereby enable the light-emitting surface to have an overall uniform brightness. The optical sheet 600 includes a diffusion sheet 610 and at least one prism sheet 620. The optical sheet 600, which is disposed over the light guide plate 400, functions to uniformly distribute brightness of the light emitted from the light guide plate 400.

The receiving member 3000, which receives the display assembly 1000 and the backlight assembly 2000, includes the mold frame 700 and a bottom chassis 800. The mold frame 700 is formed in a rectangular frame shape, and receives the backlight assembly 2000 and the display assembly 1000 in sequence. That is, elements of the backlight assembly 2000 are received inside the mold frame 700 in sequence, and the LCD panel 100 is placed over the mold frame 700. In an exemplary embodiment of the present invention, a receiving space is formed in a bar shape at one side of the bottom of the mold frame 700 in a direction perpendicular to a major direction of the mold frame 700. The FPCB 220 connected to the LCD panel 1000 is bent and the electronic components 240 provided on one surface of the FPCB 220 are received in the receiving space. The bottom chassis 800 receives and supports a plurality of sheets and the LCD panel 100 received in the mold frame 700, and is coupled with a top chassis (not shown), thereby fixing the display assembly 1000 and the backlight assembly 2000 together.

In an exemplary embodiment of the present invention, the FPCB 220 is bent toward a rear side of the bottom chassis 800, the electronic components 240 disposed on the surface of the FBCB 220 are received in a receiving space 710 of the mold frame 700, and the FPCB 220 is bonded to the rear side of the reflection plate 500 by means of a bonding member 900. The bonding member 900 may be, for example, a double-sided tape.

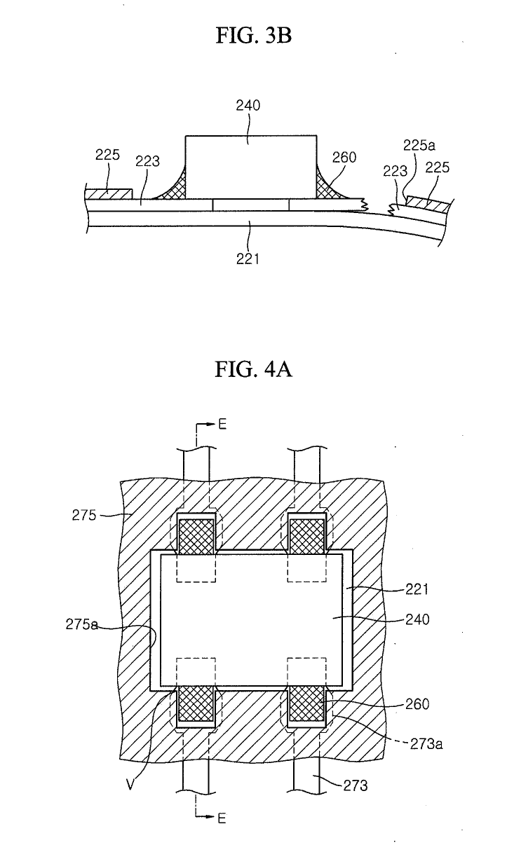

The FPCB 220 may be bonded to the bottom chassis 800. A mounting portion of the electronic component 240 provided on one surface of the FPCB 220 is bent and extended due to the bending of the FPCB in the conventional PCB assembly, which may cause the mounting portion of the electronic component 240 to be cracked. This will be more fully described, below, with reference to FIGS. 3A and 3B.

FIG. 3A is a plan view illustrating an example of a conventional PCB assembly. FIG. 3B is a cross-sectional view taken along line C-C of FIG. 3A.

Referring to FIGS. 3A and 3B, the conventional PCB assembly shown includes a base 221, a conductive pattern 223 and a coverlay 225. An electronic component 240 is mounted on the base 221, and the conductive pattern 223 is disposed between the electronic component 240 and the base 221. To mount the electronic component 240 on the conductive pattern 223, the electronic component is bonded to the conductive pattern 223 by means of soldering 260 or the like. The coverlay 225 is provided to protect the conductive pattern 223. As shown in FIGS. 3A and 3B, one surface of the conductive pattern 223 is exposed and the other surface is in contact with the base 221. The electronic component 240 is mounted in a region 225a where a portion of the coverlay 225 is removed to expose a portion of the conductive pattern 223. In such a structure, a portion of a region where the coverlay 225 is removed to expose the conductive pattern 223, that is, a region where the conductive pattern 223 is exposed but the soldering 260 is not formed may be cracked, as the thin copper conductive pattern 223 having a relatively weak bonding force is bent and extended due to bending of the base 221.

A PCB assembly according to an exemplary embodiment of the present invention employs a structure in which a portion of the conductive pattern is extended to prevent the cracking of the thin copper conductive pattern, and the extended region is fixed using coverlay. In an exemplary embodiment of the present invention, a tensile force applied to a portion of the conductive pattern having a relatively weak bonding force is dispersed even though the base is bent, and cracking of the conductive pattern can be prevented.

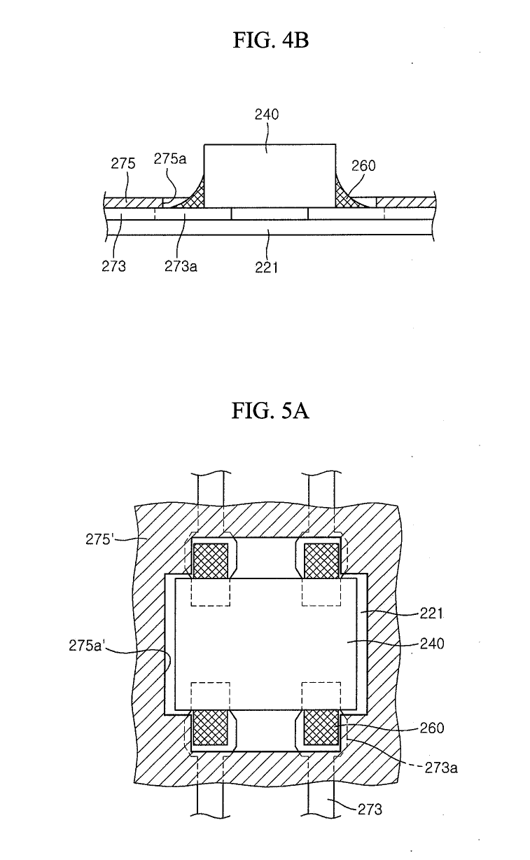

FIG. 4A is a plan view of a PCB assembly in accordance with an exemplary embodiment of the present invention. FIG. 4B is a cross-sectional view taken along line E-E of FIG. 4A.

Referring to FIGS. 4A and 4B, at least one conductive pattern 273 is provided on a base 221, and it is covered and protected by a coverlay 275. Through an opening 275a provided in the coverlay 275, a mounting unit, e.g., an electronic component 240, is mounted on the conductive pattern 273 by means of a bonding member, such as soldering 260.

The conductive pattern 273 is formed of a metal such as copper and connected to one side of the electronic component 240. A plurality of conductive pattern 273 may be provided, for example, according to the requirements of the electronic component 240. Ends of the one or more conductive patterns 273 are connected to corresponding electronic component 240, and the conductive pattern 273 is shaped such that it extends from the electronic component 240. The conductive pattern 273 connected to the electronic component 240 has a pad 273a having an enlarged area at a connection part therebetween.

The pad 273a protrudes from the conductive pattern 273 and is shaped such that the protruding portion extends in a widthwise direction, which may be defined as a direction crossing the longitudinal axial direction of the conductive pattern 273. For example, the pad 273a has a greater width than the conductive pattern 273 in a direction crossing a lengthwise direction of the conductive pattern 273. The pad 273a protruding from the conductive pattern 273 is covered and fixed by the coverlay 275. In an exemplary embodiment of the present invention, coverlay 275 is designed to cover the pad 273a, and though the PCB is bent, the tensile force applied to the conductive pattern 273 is dispersed over the pad 273a by virtue of the structure of the pad 273a protruding from the conductive pattern 273. The dispersed force is suppressed by the coverlay 275 covering and fixing the pad 273a. The pad 273a extending from the conductive pattern 273 is disposed at a connection part between the conductive pattern 273 and the electronic component 240. The pad 273a may have a larger plane area than that of the soldering 260, and may have a greater width than the soldering 260 in the widthwise direction, i.e., with respect to the lengthwise direction of the conductive pattern 273. It is to be understood that the pad 273a may have a larger area than it appears in the drawings. The pad 273a may have a larger area than an area of the opening 275a.

To mount the electronic component 240 on the plurality of conductive patterns 273, the soldering 260 may be applied as a bonding member to a joint between the electronic component 240 and each conductive pattern 273. For example, the soldering 260 may be formed to fix the top surface of the conductive pattern 273 and the side surface of the electronic component 240 together. The electronic component 240 may be disposed on the conductive pattern 273 and connected to the conductive pattern 273 through the bottom surface thereof.

The coverlay 275 is provided over the conductive pattern 273 to cover the conductive pattern 273 extending from the electronic component 240. For example, the coverlay 275 may be provided over the conductive pattern 273 except for a region where the electronic component 240 and the soldering 260 are provided. In various exemplary embodiments of the present invention, the coverlay 275 is provided over the conductive pattern 273 to cover the conductive pattern 273 and has the opening 275a therein. Inside the opening 275a, the electronic component 240 and the soldering 260 for mounting the electronic component 240 on the conductive pattern 273 can be provided.

A circumferential surface of the opening 275a of the coverlay 275 may be formed over the conductive pattern 273. According to the plan view, sides of the circumferential surface of the opening 275a are formed of lines having at least two directions. For example, the circumferential surface of the opening 275a of the coverlay 275 may be bent to have a vertex V as illustrated in FIG. 4A. The circumferential surface of the opening 275a may be curved so that a vertex V is not formed.

The number of the vertices formed by the circumferential surface of the opening 275a of the coverlay 275 may be at least one. A vertex may be positioned over the pad 273a that is a connection part between the conductive pattern 273 and the electronic component 240.

In this way, because the vertex V of the circumferential surface of the opening 275a of the coverlay 275 is disposed at the pad 273a, the coverlay 275 supports the bending of the pad 273a extending from the conductive pattern 273, particularly in a region near the soldering 260, and flex cracking can be prevented.

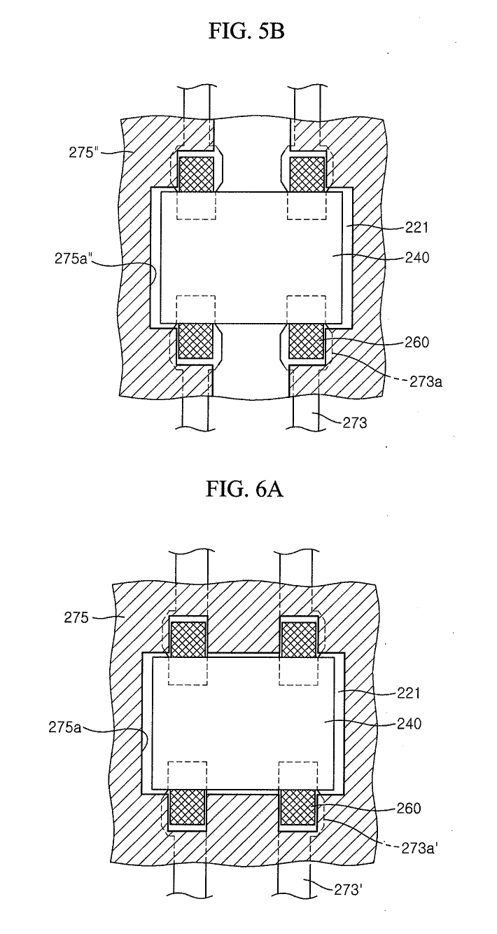

FIGS. 5A and 5B are plan views illustrating the PCB assembly of FIG. 4A, according to exemplary embodiments of the present invention.

While the circumferential surface of the opening 275a of the coverlay 275 has four vertices over the pad 273a of one conductive pattern 273 in the structure of FIGS. 4A and 4B, a PCB assembly may have a structure, as shown in FIG. 5A, in which a circumferential surface of an opening 275a′ of a coverlay 275′ has two vertices over a pad 273a of one conductive pattern 273.

The coverlay 275′ of FIG. 5A can be more easily fabricated and allow a larger tolerance during fabrication as compared to the structure of FIGS. 4A and 4B. For example, in the PCB assembly of FIGS. 4A and 4B, the coverlay 275 is disposed between two conductive patterns 273 adjacent to each other so that a dimensional accuracy is necessarily required. That is, the structure of FIGS. 4A and 4B allows smaller tolerance than the structure of FIG. 5A, which may lead to a decrease of product yield when mounting the electronic component 240 having a microvolume.

Referring to FIG. 5B, a coverlay 275″ may have an opening 275a″ further extending toward a region where the conductive pattern is not provided, e.g., in a lengthwise direction along which the conductive pattern 273 extends from the electronic component 240. This structure also allows a larger tolerance than the structure of FIGS. 4A and 4B. Therefore, manufacturing cost for the coverlay 275″ can be reduced since the opening 275a″ is formed over the region where the conductive pattern 273 is not provided.

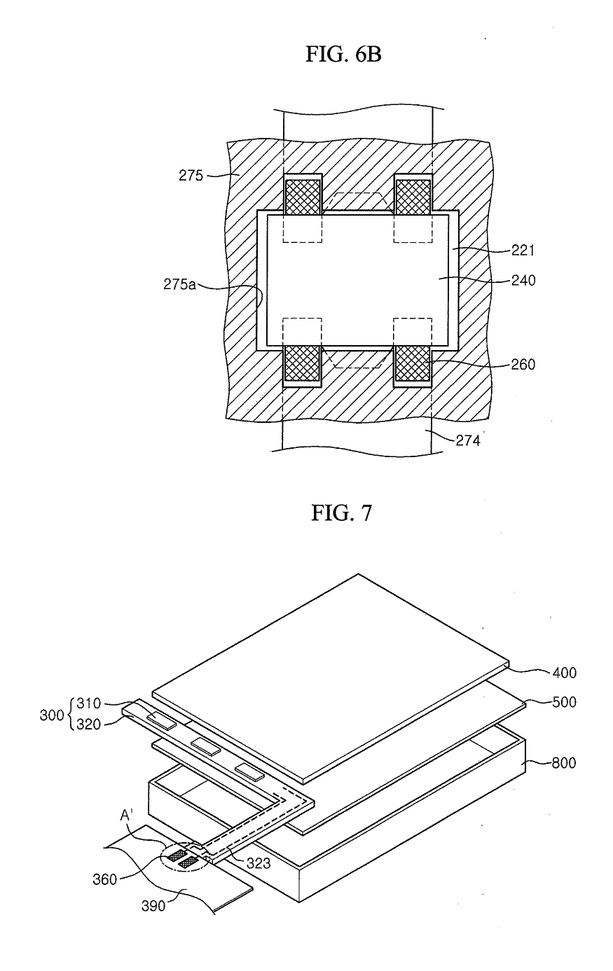

FIGS. 6A and 6B are plan views of the PCB assembly of FIG. 4A, according to exemplary embodiments of the present invention.

In FIGS. 6A and 6B, the coverlayer 275 has a similar structure to that of FIG. 4A, except for the structure of the conductive pattern.

Referring to FIG. 6A, a pad 273a′ is formed on the conductive pattern 273′, wherein the pad 273a′ extends from a connection part between the conductive pattern 273′ and the electronic component 240. The pad 273a′ of FIG. 6A protrudes in one direction along the width of the conductive pattern. The pad 273a′ protrudes from a region corresponding to the soldering 260 which is formed at a joint between the electronic component 240 and the conductive pattern 273′. For example, the pad 273a′ is shaped to protrude outward in opposite directions from two adjacent pads 273a′.

Such a structure can further ensure a space between adjacent conductive patterns 273′ in comparison with the structures illustrated in FIGS. 4A through 5B, which may further prevent a short circuit between the conductive patterns 273′, particularly between pads 273a′, which may be caused by torsion or the like. The conductive patterns 273′ may be densely arranged to increase the degree of integration.

Compared to the structure of 6A, FIG. 6B illustrates a structure where adjacent conductive patterns 274 are connected. That is, one conductive pattern 274 is branched into two sub-conductive patterns which are connected to the electronic component 240 through the soldering 260. For example, the structure of FIG. 6B is applicable to the case where there is no problem when the conductive patterns 274 are connected to each other depending on the electronic component 240, unlike the structure of FIG. 6A where the adjacent conductive patterns 273′ are separated from each other. In this case, a yield stress of the conductive pattern 274 during the bending may be greater than those of the structures illustrated in FIGS. 4A through 5B.

Hereinafter, exemplary embodiments in which a PCB is applied to a backlight assembly will be described.

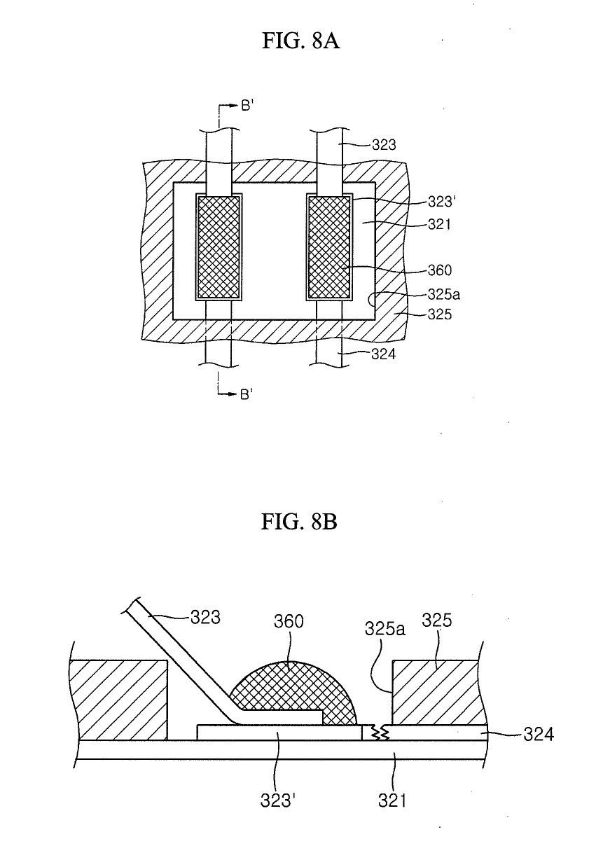

FIG. 7 is an exploded perspective view illustrating a portion of a backlight assembly, according to an exemplary embodiment of the present invention.

Referring to FIG. 7, the backlight assembly includes a light source 300, a light guide plate 400 coupled with the light source 300, and a reflection plate 500 provided under the light guide plate 400. The light source 300, which is provided at a side of the light guide plate 400, includes LEDs 310 and a substrate 320 having the LEDs 310 mounted thereon. The LED 310 is a side view type LED, and emits light toward a side plane of the light guide plate 400. The substrate 320 having the LEDs 310 mounted thereon includes an FPCB 323 with good flexibility. The FPCB 323 includes circuitry therein and extends to the outside. The FPCB 323 supplies power, which is supplied from the PCB 390 connected to the FPCB 323 by a bonding member 360, to the LED 310 through the circuitry provided in the FPCB 323. The PCB 390 may be a PCB that controls supplying of power to the LED 310 according to an external signal.

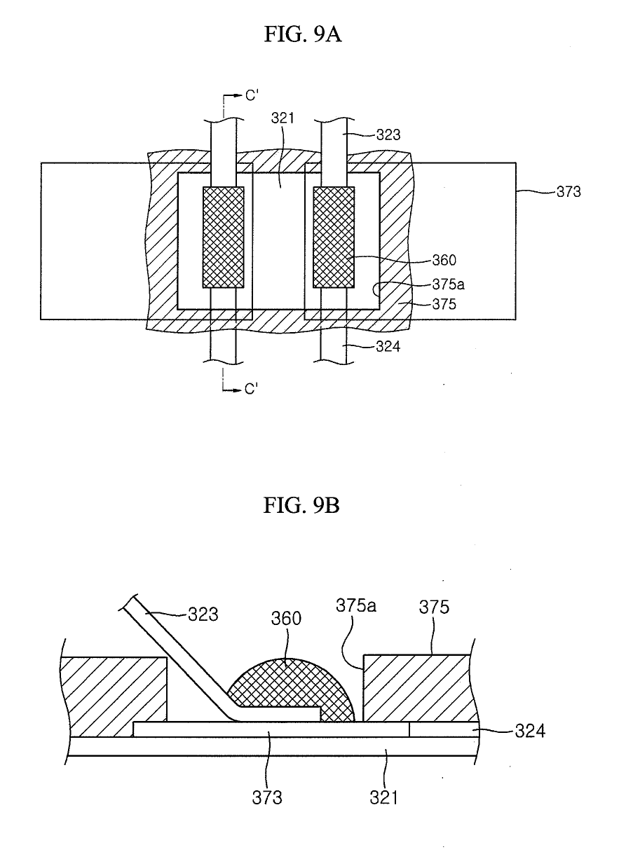

FIG. 8A is a plan view illustrating an example of a conventional PCB assembly. FIG. 8B is a cross-sectional view taken along line B′-B′ of FIG. 8A.

Referring to FIGS. 8A and 8B, the conventional PCB assembly includes a base 321, a conductive pattern 324 and a coverlay 325. A mounting unit, e.g., a PCB 323 including a circuit extending from the LED (such as LED 310 of FIG. 7), is attached on a pad 323′, and the pad 323′ is connected to the conductive pattern 323. The PCB 323 is bonded to the pad 323′ through a bonding member, such as soldering 360, so as to mount the PCB 323 on the pad 323′. The coverlay 325 is provided to protect the conductive pattern 324. In conventional PCB assembly, the coverlay 325 may be spaced apart from the pad 323′ by a distance ranging from approximately 0.1 mm to approximately 0.2 mm. The conductive pattern 324 exposed in this space may be cracked due to a tensile force applied thereto caused by the bending of the base 321.

In an exemplary embodiment of the present invention, the pad extends to the bottom portion of the coverlay and the conductive pattern is not exposed. Instead, the pad, which may have a relatively higher yield stress, is exposed, and cracking of the conductive pattern may be prevented.

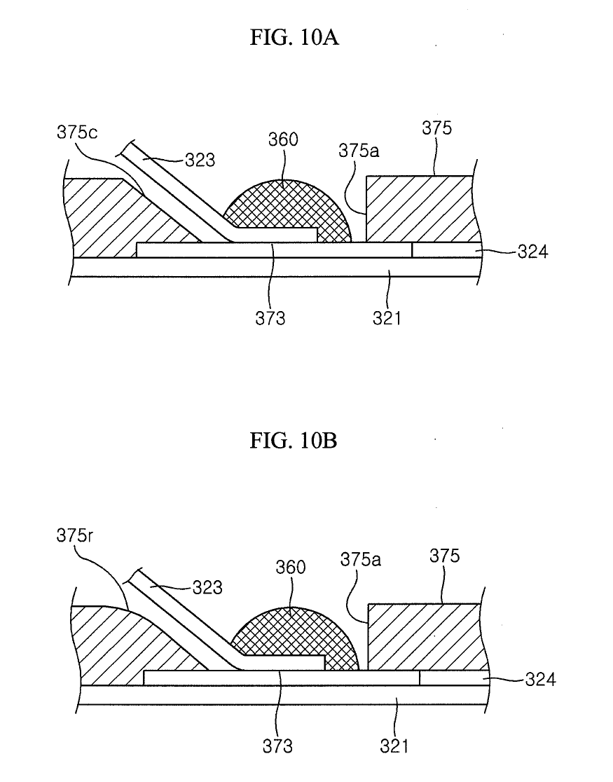

FIG. 9A is a plan view of a PCB assembly in accordance with an exemplary embodiment of the present invention. FIG. 9B is a cross-sectional view taken along line C′-C′ of FIG. 9A.

Referring to FIGS. 9A and 9B, at least one conductive pattern 324 and a pad 373 connected to the conductive pattern 324 are disposed on a base 321. The thickness of the pad 373 may be greater than or substantially the same as that of the conductive pattern 324. The thickness of the pad 373 may be thinner than that of the conductive pattern 324, for example, depending on a material characteristic.

The conductive pattern 324 is covered and protected by the coverlay 375. One portion of the pad 373 is exposed through an opening 375a provided in the coverlay 375, and the other portion of the pad 373 is covered with the coverlay 375. A mounting unit, e.g., a PCB 323 including the conductive pattern extending from the LED (such as LED 310 of FIG. 7), is mounted on the portion of the pad 373 exposed through the opening 375a of the coverlay 375 using a bonding member 360, such as for example, soldering.

The conductive pattern 324, which may be formed of a metal such as copper, extends from the pad 373 and is covered and protected by the coverlay 375. The pad 373 extends in at least one direction in the plan view. For example, the pad 373 extends to the bottom portion of the coverlay 375 in a direction crossing the extension direction of the conductive pattern 324, and also extends beyond the opening 375a of the coverlay 375. As such, one portion of the pad 373 is exposed through the opening 375a and the other portion is covered with the coverlay 375. That is, the pad 373 may have a greater width than the conductive pattern 324 in a widthwise direction crossing a lengthwise direction of the conductive pattern 324.

In an exemplary embodiment of the present invention, the conductive pattern 324 is covered with the coverlay 375 and the pad 373 is exposed through the opening 375a of the coverlay 375, and a tensile stress, which is applied to the conductive pattern 324 due to the bending of the base 321, is dispersed over the coverlay 375, and a portion configured with the conductive pattern 324 and the coverlay 375 may have a higher yield stress. The thickness of the pad 373 may be greater than or substantially the same as that of the conductive pattern 324. For example, in a case when the conductive pattern 324 has a greater thickness than the conductive pattern 324, the pad 373 has a higher yield stress than the conductive pattern 324, whereby cracking of the conductive pattern 324 due to a tensile stress caused by bending can be prevented. The thickness of the pad 373 may be thicker than that of the conductive pattern 324, particularly when yield stress of the pad 373 material is higher than that of the conductive pattern 324 material.

The portion of the pad 373 exposed by the opening 375a of the coverlay 375 may have a smaller area than the portion covered with the coverlay 375. The pad 373 may have a greater area than the opening 375a. The pad 373 has a predetermined yield stress. Accordingly, to prevent the crack of the pad 373, the portion of the pad 373 covered with the coverlay 375 may have an area equal to or greater than the other portion exposed through the opening 375a. To obviate a short between the pads 373, the pad 373 may extend in opposite directions to mutually facing directions of two adjacent pads 373.

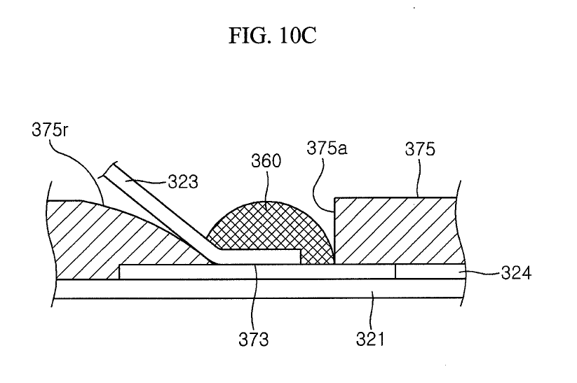

FIGS. 10A to 10C are schematic views illustrating variants of the exemplary embodiment of the present invention.

Referring to FIG. 10A, a chamfer 375c is provided on an inner circumferential surface of the coverlay 375 having the opening 375a. The chamfer 375c is provided so that the PCB 323 mounted on the pad 373 may not contact the coverlay 375. The chamfer 375c may be inclined as gentle as possible.

Referring to FIG. 10B, a curved surface 375r is provided on an inner circumferential surface of the coverlay 375 that forms the opening 375a. The curved surface 375r is provided so that the PCB 323 mounted on the pad 373 may not contact the coverlay 375. The curved surface 375r may be curved as gentle as possible.

Referring to FIG. 10C, the curved surface 375r is provided on the inner circumferential surface of the coverlay 375 that forms the opening 375a. The pad 373 is covered by the coverlay 375 or the bonding member 360, and is not exposed through the opening 375a. In this configuration of the PCB, concentration of stress on the exposed portion of the pad 373 can be prevented. The coverlay 375 is extended to contact the bonding member 360 or the bonding member 360 is extended to contact the coverlay 375 to prevent the concentration of stress on the exposed portion of the pad 373. Although the coverlay 375 illustrated in FIG. 10C includes the curved surface 375r, the present invention is not limited thereto. That is, various coverlays 375 having different configurations are applicable.

In a PCB and an LCD having the same in accordance with the various exemplary embodiments of the present invention, crack of a conductive pattern, for example, caused by a bending or a flection, can be prevented by increasing an area of the conductive pattern and covering the conductive pattern with a coverlay, and the reliability of an electronic device having a PCB as well as a display having the same may be improved.

It is to be understood that the coverlay structure according to exemplary embodiments of the present invention is also applicable to other conductive pattern structures.

Although it has been exemplarily illustrated that an FPCB structure according to exemplary embodiments of the present invention can be applied to an LCD, the FPCB structure described herein can also be used in other displays or other electronic devices employing the FPCB. Although exemplary embodiments of the present invention have been described with reference to the accompanying drawings for the purpose of illustration, it is to be understood that the inventive processes and circuits are not to be construed as limited thereby. It will be readily apparent to those of ordinary skill in the art that various modifications to the foregoing exemplary embodiments may be made without departing from the scope of the invention as defined by the appended claims, with equivalents of the claims to be included therein.

What is claimed is:

1. A printed circuit board (PCB) assembly, comprising:
a base;
a conductive pattern disposed on the base;
a pad provided on a portion of the conductive pattern;
a mounting unit disposed on the pad for electrically connecting the conductive pattern; and
a coverlay having an opening that exposes the mounting unit, the coverlay covering the conductive pattern,
wherein an area of the pad is larger than an area of the opening.

2. The PCB assembly of claim 1, further comprising an electronic component electrically connected to the conductive pattern over the mounting unit using a bonding member.

3. The PCB assembly of claim 1, wherein a chamfer or a curved surface is provided in the opening of the coverlay.

4. The PCB assembly of claim 1, wherein the pad has a greater width than the conductive pattern in a first direction, the first direction crossing a longitudinal axial direction of the conductive pattern.

5. A printed circuit board (PCB) assembly, comprising:
a base;
a PCB comprising a first conductive pattern disposed on the base;
a pad provided on the first conductive pattern;
a coverlay configured to cover the first conductive pattern; and
an electronic component mounted on the PCB,
wherein the electronic component is mounted on the pad to be connected to the first conductive pattern of the PCB by a bonding member, and the coverlay has an opening which exposes the pad, an area of the pad being larger than an area of the opening.

6. The PCB assembly of claim 5, wherein a circumferential surface of the opening of the coverlay is provided over the pad, and wherein sides of the circumferential surface of the opening are formed of lines having at least two directions.

7. The PCB assembly of claim 6, wherein the circumferential surface of the opening has a curved shape over the pad.

8. The PCB assembly of claim 5, wherein the pad protrudes in a different direction from a longitudinal direction of a second conductive pattern disposed adjacent to the first conductive pattern.

9. The PCB assembly of claim 5, wherein the bonding member contacts the coverlay.

10. A printed circuit board (PCB) assembly, comprising a PCB,
wherein the PCB comprises at least one first conductive pattern disposed on a base; and a coverlay which has an opening and covers the first conductive pattern;
the first conductive pattern comprises a first pad, on which a bonding member is placed, and an conductive pattern extending from the first pad, the first pad comprising an exposed region that is exposed by the opening of the coverlay and a shielded region that is covered by the coverlay; and
an area of the shielded region of the first pad is equal to or greater than an area of the exposed region.

11. The PCB assembly of claim 10, wherein the first pad protrudes in a different direction from a protruding direction of a second pad disposed adjacent to the first pad.

12. The PCB assembly of claim 10, further comprising a second conductive pattern connected to the first conductive pattern on the PCB by the bonding member.

13. A display, comprising:
a display panel configured to display an image; and
a printed circuit board (PCB) having a first side connected to the display panel, a plurality of electronic components mounted on the first side of the PCB, the PCB comprising at least one conductive pattern disposed on a base, and a coverlay configured to cover the conductive pattern,
wherein the electronic component is mounted to be connected to the conductive pattern of the PCB by a bonding member, and the coverlay has an opening corresponding to a position where the electronic component and the bonding member are provided.

14. The display of claim 13, wherein the PCB is provided by bending the other side of the PCB toward a rear side of the display panel.

15. The display of claim 13, wherein the PCB comprises a flexible PCB.

16. A display, comprising:
a printed circuit board (PCB) assembly; and
a light source configured to receive power from the PCB assembly,
wherein the PCB assembly comprises a PCB which includes: at least one first conductive pattern or more disposed on a base; and a coverlay that has an opening and covers the first conductive pattern,
and wherein the first conductive pattern comprises a pad on which a bonding member is placed and a conductive pattern extending from the pad, the pad comprising an exposed region that is exposed by the opening of the coverlay, and a shielded region that is covered by the coverlay.

17. The display of claim 16, wherein the light source comprises at least one light-emitting diode (LED).
